(19) United States
(12) Patent Application Publication
(10) Pub. No.: US 2026/0372146 A1
(43) Pub. Date: Nov. 19, 2026

(54) CORE-TO-CORE CONNECTIONS

(71) Applicant: Advanced Micro Devices, Inc., Santa Clara, CA (US)

(72) Inventors: Prithwish CHATTERJEE, Austin, TX (US); Sri Ranga Sai BOYAPATI, Austin, TX (US); Robert Grant SPURNEY, Austin, TX (US); Deepak Vasant KULKARNI, Austin, TX (US); William James LAMBERT, Phoenix, AZ (US); Raja SWAMINATHAN, Austin, TX (US)

(21) Appl. No.: 19/423,838

(22) Filed: Dec. 17, 2025

Related U.S. Application Data
(60) Provisional application No. 63/805,759, filed on May 14, 2025.

(51) Int. Cl. H10W 70/68; H10W 70/63; H10W 74/10

(52) U.S. Cl. CPC H10W 70/682; H10W 70/63; H10W 74/114

(57) ABSTRACT

Integrated circuit (IC) modules having one or more IC devices embedded into a core of a multicore substrate are provided, along with electronic devices and chip packages having the same. In one example, an integrated circuit (IC) module is provided. The IC module includes a first core, an IC device, and a second core. The first core has a first face, a second face, and a cavity. The cavity is formed in the first core and open through the first and second faces of the first core. The IC device is disposed in the cavity of the first core. The second core has a first face that is laminated to the second face of the first core.

### CROSS REFERENCE TO RELATED APPLICATIONS

This application claims benefit of United States Provisional Patent Application No. 63/805,759, filed May 14, 2025, which is incorporated by reference in its entirety.

### TECHNICAL FIELD

Embodiments of the present disclosure generally relate to multi-core substrates, chip packages and electronic devices having the same. In particular, electronic devices having multi-core substrates, where one or more IC devices are disposed a cavity of at least one core of the multi-core substrate.

### BACKGROUND

Data center graphic and central processing units have seen power consumption recently increase from 550-750 watts to 2.5 kilowatts, and is expected to approach or exceed 5 kilowatts in the not so distant future. This increase in power density requires the development of advanced solutions to manage the heightened electrical and thermal loads effectively. Active components such as voltage regulators are essential in meeting these demands. They enable dynamic voltage adjustment in response to workload changes, optimizing power usage during low activity periods and boosting performance during peaks.

To address electrical challenges, particularly those related to efficiency, a specialized class of active components must be integrated into the architecture. These components can modulate power requirements and support dynamic voltage scaling by leveraging active silicon devices. This capability allows processors to adjust voltage levels in real time based on workload demands, optimizing power consumption during periods of low activity and enhancing performance during peak operations. However, such components require physical space, which is limited; therefore, embedding them within the core presents an attractive alternative..

The development of advanced power delivery solutions involving active silicon such as voltage regulator and integration with high efficiency inductors could improve platform efficiency, however these solutions presents several challenges from an embedding perspective. Currently, the industry trend mandates that embedded components closely match the core thickness, requiring intricate design and manufacturing processes.

For higher compute power demands, such as those anticipated for next generation AI devices, larger and more complex die designs are necessary. This translates into a significant increase in the number of integrated voltage regulators needed. The manufacturing process must also accommodate substrates with exceptionally thick cores to address warpage concerns, but this also necessitates matching component thickness.

Presently, component manufacturing faces limitations with a substrate thickness cap around approximately 800 micrometers, which is insufficient for embedding extremely thick components. Moreover, future demands may necessitates much larger counts of embedded components, such as in the order of hundreds of components, all within the constraints of matching core and component thickness. Unfortunately, current designs cannot scale and would ultimately cause surface mount component and warpage challenges.

The inventors have recognized limitations the need for innovative solutions in embedding and materials engineering to accommodate the rising demands of power density and component integration in advanced computing systems.

### SUMMARY

Core-on-core substrate architectures and techniques for fabricating the same are provided that includes one or more IC devices embedded in one or more cores of a multicore substrate, along with electronic devices and chip packages having the same.

In one example, an integrated circuit (IC) module is provided. The IC module includes a first core, an IC device, and a second core. The first core has a first face, a second face, and a cavity. The cavity is formed in the first core and open through the first and second faces of the first core. The IC device is disposed in the cavity of the first core. The second core has a first face that is laminated to the second face of the first core.

In another example, a chip package is provided. The chip package includes a first core, a second core, first built-up layers, an integrated circuit (IC) device, and an integrated circuit (IC) die. The first core has a first face, a second face, and a cavity. The cavity is formed in the first core and is open through the first and second faces of the first core. The first IC device is disposed in the cavity of the first core. The second core has a first face laminated to the second face of the first core. The first built-up layers are formed on the first face of the first core. The first built-up layers have first substrate routing circuitry. The IC die is disposed on the first built-up layers. The IC die has functional circuitry that is coupled to the first IC device through the first substrate routing circuitry.

In yet another example, a chip package is provided. The chip package includes substrate having a plurality of cores, an integrated circuit (IC) device, and an integrated circuit (IC) die. The IC die is disposed on the substrate. The first IC device is embedded in a core of the plurality of cores that is disposed closest to the IC die.

In another example, the IC module includes a first core, a second core, and an IC device. The first core includes a first face and a second face, where the cavity is open through the first and second faces of the substrate core. The IC device is disposed in the cavity of the first core. The cavity is open to first and second opposing faces of the substrate core. The second core has a first face laminated to the second face of the first core. In another example, the IC module includes a substrate core having a cavity and an IC device disposed in the cavity. The IC device has a height that is equal to or less than a distance defined between the first and second faces of the substrate core.

In one example, the IC module includes a sandwich core disposed between the first core the second core.

In some examples, a first side of the IC device is substantially coplanar with the first face of the substrate core.

Any of the IC modules described herein may additionally include chip package mounted on the first face of the first core.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 is a schematic side view one example of an electronic device that includes a chip package having a multi-core substrate, the chip package including an integrated circuit (IC) device embedded in at least one core of the multi-core substrate.

FIG. 2 is a schematic side view one example of the multi-core substrate of FIG. 1.

FIG. 3 is a block diagram of a method for fabricating a multi-core substrate having one or more IC devices embedded in at least one core of the multi-core substrate.

FIGS. 4A-4E are schematic side views of a multi-core substrate having an embedded IC device during various stages of fabrication.

FIG. 5 is a schematic side view another example of an electronic device that includes a chip package having a multi-core substrate, the chip package including an integrated circuit (IC) device embedded in at least one core of the multi-core substrate.

FIG. 6 is a block diagram of another method for fabricating a multi-core substrate having one or more IC devices embedded in each of at least two cores of the multi-core substrate.

FIGS. 7A-7E are schematic side views of another multi-core substrate having embedded IC devices during various stages of fabrication.

To facilitate understanding, identical reference numerals have been used, where possible, to designate identical elements that are common to the figures, and a second-case letter added where the elements are substantially the same. It is contemplated that elements of one embodiment may be beneficially incorporated in other embodiments.

### DETAILED DESCRIPTION

Disclosed herein are examples of core-on-core substrate architecture that enhances power delivery and component integration. This unique architecture includes a substrate comprised of two or more laminated substrate cores, with one or more integrated circuit (IC) devices embedded in one of the substrates cores. The IC devices may include one or both active and passive components, including silicon elements like integrated voltage regulators, as well as inductors and capacitors. In some embodiments, this core-on-core configuration allows active elements to be positioned in the substrate core closest to an IC die mounted on the substrate (i.e., embedded in the substrate core closest to the IC die), thus, improving electrical performance, reliability, and efficiency.

A novel architecture and technique is proved where thinner components are embedded within a core matched to their thickness. This approach minimizes the risk of void formation during embedding. Additionally, a separate core with increased thickness will be introduced to mitigate warpage concerns.

Innovative manufacturing methods are employed, such as laser via drilling within a mechanically drilled through-hole, where the mechanically drilled through-hole is part of a semi-preformed core combined with propylene glycol material. Specifics of this process, along with associated design rules, are detailed herein.

The integration of asymmetric or symmetric cores will facilitate the creation of a hybrid core with a desired thickness. This hybrid core design addresses warpage issues and enables robust two-sided connections, as outlined in the following sections.

This solution provides a method for integrating cores with two different thicknesses, allowing vertical connections through the substrate core. This approach enables direct metal connections and patterning options. Specifically, a first core is configured matches the component (i.e., IC device) thickness, while a second core provides additional structural thickness to address warpage concerns.

This solution addresses mitigates issues relating to increased substrate thickness. Additionally, this solution is scalable as the “core thickness” and be further increased in the future without invoking components thicker than 1.5 mm. Adding more layers to a multilayer core results in diminishing returns, as excessive prepreg layers impact the coefficient of thermal expansion (CTE).

The method reduces the need for laser drilling, opening the possibility of sourcing alternative core suppliers and seconding costs.

The approach allows for linear increases in core thickness as required by alternate technologies, resulting in reduced embedding costs, better throughput, and improved overall assembly yield. This approach significantly alleviates capacity constraints on competing substrate technologies, as the cost associated with ablating a thick core using lasers is avoided, which constitutes a significant percentage of the total embedding costs.

Additionally, there is potential to conduct extra testing before integrating the first core (after establishing component connections), enhancing the reliability of subsequent connections. This refined strategy not only resolves current challenges but also improves cost efficiency and technological adaptability.

Some advantages over conventions designs include improved scalability due to the multi-thickness cores. Integration of two or more cores allows one core to match the embedded component (IC device) thickness, with at least one other core providing structural support to mitigate warpage. Thus, if core thickness increase in the future to support larger die complexes, the multi-core substrate architecture is readily scalable. Additionally, vertical connections through the multi-core substrate enables direct metal connections and patterning through the substrate for improved electrical performance. Moreover, the multi-core substrate architecture reduces the number of prepreg layers needed. Reducing the number of prepreg layers maintains a stable coefficient of thermal expansion (CTE) when compared with existing technology. Multi-core substrates also have improved CTE by reducing the amount of copper in the core as compared to conventions designs.

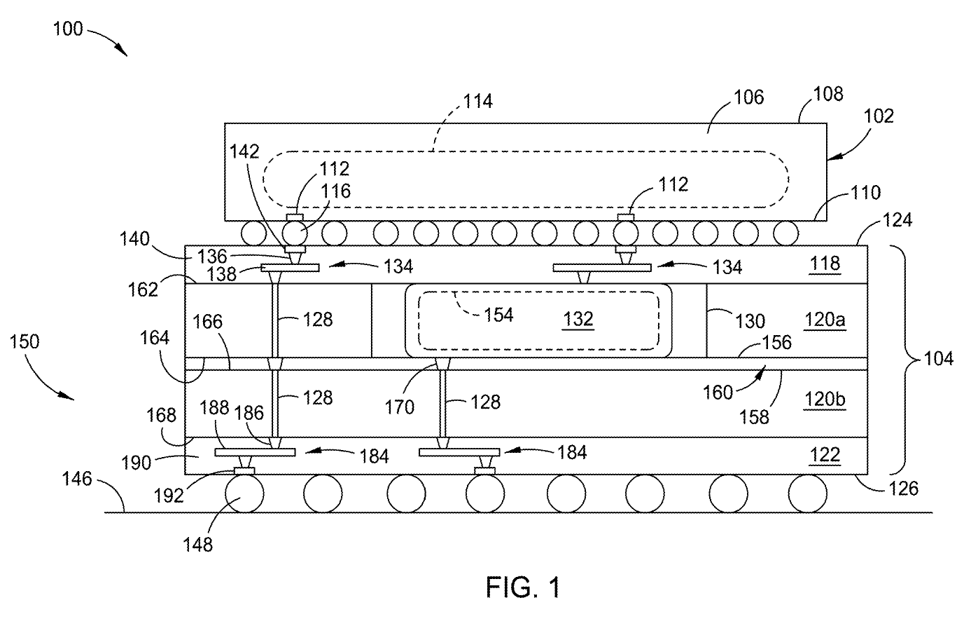

Turning now to FIG. 1, is a schematic side view one example of an electronic device 150 that includes a chip package 100 having a multi-core substrate 104 is provided. The chip package 100 includes an integrated circuit (IC) device 132 embedded in at least one core 120 of the multi-core substrate 104. The electronic device 150 includes the chip package 100 mounted on a printed circuit board 146. The chip package 100 may be mounted on a printed circuit board (PCB) 146 using a socket, wire bonding, solder balls, or other suitable technique. In the example illustrated in FIG. 1, the chip package 100 electrically and mechanically coupled to the PCB 146 using solder balls 148.

The chip package 100 includes one or more IC dies 102 disposed on a multi-core substrate 104. Although only one IC die 102 is illustrated in FIG. 1, one or more IC dies maybe vertically stacked one on top of the other, and/or laterally stacked side-by-side on the multi-core substrate 104.

The body 106 of the IC die 102 includes a first face 108 and a second face 110. The body 106 of the IC die 102 includes functional circuitry 114. The functional circuitry 114 is disposed within the body 106 of the IC die 102 and may include compute and/or logic circuitry. In one example, the functional circuitry 114 is configured as a processor, such as a central processing unit (CPU) or a graphics processing unit (GPU). The functional circuitry 114 terminates at a contact pad 112 exposed on the second face 110 that faces the multi-core substrate 104.

The second face 110 of the IC die 102 is electrically and mechanically coupled to the multi-core substrate 104. In one example, interconnects 116 couple the contact pads 112 exposed on the second face 110 of the IC die 102 to the routing circuitry of the multi-core substrate 104. The interconnects 116 may be solder balls, or alternatively, the interconnects maybe a hybrid bonding layer formed on the multi-core substrate 104.

The multi-core substrate 104 depicted in FIG. 1 is configured as a package substrate. However, the multi-core substrate 104 may also be configured an interposer disposed between a package substrate 104 and the IC die 102.

The multi-core substrate 104 includes a first built-up layer 118, a plurality of cores 120, and a second built-up layer 122. The plurality of cores 120 include at least a first core 120a and a second core 120b. The multi-core substrate 104 has a first face 124 and a second face 126. The first face 124 faces the second face 110 of the IC die 102. One side of the first built-up layer 118 forms the first face 124 of the multi-core substrate 104, while the opposite side of the first built-up layer 118 is disposed in contact with a first face 162 of the first core 120a. Similarly, one side of the second built-up layer 122 forms the second face 126 of the multi-core substrate 104, while the opposite side of the second built-up layer 122 is disposed in contact with the second core 120b.

The cores 120a, 120b of the multi-core substrate 104 are generally formed from an inorganic material, such as silicon, ceramic, glass reinforced plastic, and the like. The cores 120a, 120b of the multi-core substrate 104 may alternatively be formed from other rigid materials. The first cores 120a includes a first face 162 and a second face 164. The second core 120b includes a first face 166 and a second face 168. The first built-up layer 118 is disposed on the first face 162 of the first core 120a. The second built-up layer 122 is disposed in contact with the second face 168 of the second core 120b.

A recess 130 is formed in the first core 120a. The recess 130 may be in the form of a cavity that extends from the first face 162 into the first core 120a. In the example depicted in FIG. 1, the recess 130 extends from the first face 162 and exits the second face 164 of the first core 120a, thus forming a passage completely through the first core 120a.

The IC device 132 is disposed in the recess 130. The IC device 132 does not extend beyond the faces 162, 164 of the first core 120a. In one example, the IC device 132 is a pre-fabricated unitary component that secured in the recess 130. The IC device 132 generally has a height that is substantially the same as a thickness of the first core 120a. In one example, the thickness of the first core 120a is less than about 750 µm. In another example, the thickness of the second core 120b is greater than about 750 µm.

Continuing to refer to FIG. 1, a plurality of vias 128 are disposed through the cores 120a, 120b. The vias 128 are filled with a conductive material, such as copper. Although only one via 128 is illustrated in each of the cores 120a, 120b depicted in FIG. 1, it is to be understood that each core 120a, 120b may include many vias 128. The vias 128, particularly in the second core 120b, may be laser drilled. The vias 128 may be utilized to transmit/connect ground, power, and/or signals through the cores 120a, 120b, and are ultimately coupled to the functional circuitry 114 of the IC die 102. In other examples, one or more of the vias 128 may be configured as thermally conductive pillars, such as copper or other metal pillars, whose primarily function is to transmit heat through the cores 120a, 120b. Such vias 128 configured as thermally conductive pillars are not coupled to the functional circuitry 114 of the IC die 102.

The first built-up layer 118 generally includes patterned metal layers formed between dielectric layers 140. Although the dielectric layers 140 are illustrated in FIG. 1 as a single block of material, at least 3 or more layers of dielectric material comprise the dielectric layers 140 of the first built-up layer 118. The patterned metal layers are interconnected to form first built-up layer routing circuitry 134. The first built-up layer routing circuitry 134 is generally formed by vias 136 and lines 138. The first built-up layer routing circuitry 134 generally terminates at a contact pad 142 exposed on the first face 124 of the multi-core substrate 104. In one example, an interconnect 116, such as a microbump, is utilized to connect the contact pad 142 of the multi-core substrate 104 with the contact pad 112 of the IC die 102, thus electrically connecting the functional circuitry 114 of the IC die 102 to the first built-up layer routing circuitry 134 of the multi-core substrate 104. In another example, the interconnect 116 maybe a hybrid bonding layer that electrically connects the contact pads 112, 142 while bonding the second face 110 of the IC die 102 to the first face 124 of the multi-core substrate 104.

The first built-up layer routing circuitry 134 may be coupled to the vias 128 formed through the core 120 to provide ground, power, and/or signals through the first built-up layer 118 to the functional circuitry 114 of the IC die 102. The first built-up layer routing circuitry 134 may optionally be utilized to couple to the vias 128 configured as heat transfer pillars to route heat out of the multi-core substrate 104. The first built-up layer routing circuitry 134 is also coupled to the IC device 132 disposed in the core 120 to provide ground, power, and/or signals between the IC device 132 and the to the functional circuitry 114 of the IC die 102.

The second built-up layer 122 generally includes patterned metal layers formed between dielectric layers 190. Although the dielectric layers 190 are illustrated in FIG. 1 as a single block of material, at least 3 or more layers of dielectric material comprise the dielectric layers 190 of the second built-up layer 122. The patterned metal layers are interconnected to form second built-up layer routing circuitry 184. The second built-up layer routing circuitry 184 is generally formed by vias 186 and lines 188. One end of the second built-up layer routing circuitry 184 is connected to the vias 128 formed through the core 120 of the multi-core substrate 104. The second built-up layer routing circuitry 184 may be coupled to the first built-up layer routing circuitry 134 through the vias 128 formed through the core 120 to provide ground, power, and/or signals through the multi-core substrate 104 to the functional circuitry 114 of the IC die 102. One end of the second built-up layer routing circuitry 184 may optionally terminate and be coupled to the circuit elements (e.g., the active and/or passive devices) of the IC device 132. The other end of the second built-up layer routing circuitry 184 terminates at a contact pad 192 exposed on the second face 126 of the multi-core substrate 104. In one example, a solder ball 148 is utilized to connect the contact pad 192 of the multi-core substrate 104 with a contact pad of the PCB 146, thus forming the electronic device 150 and electrically connecting the functional circuitry 114 of the IC die 102 (and/or circuit elements of the IC device 132) to the circuitry of the PCB 146.

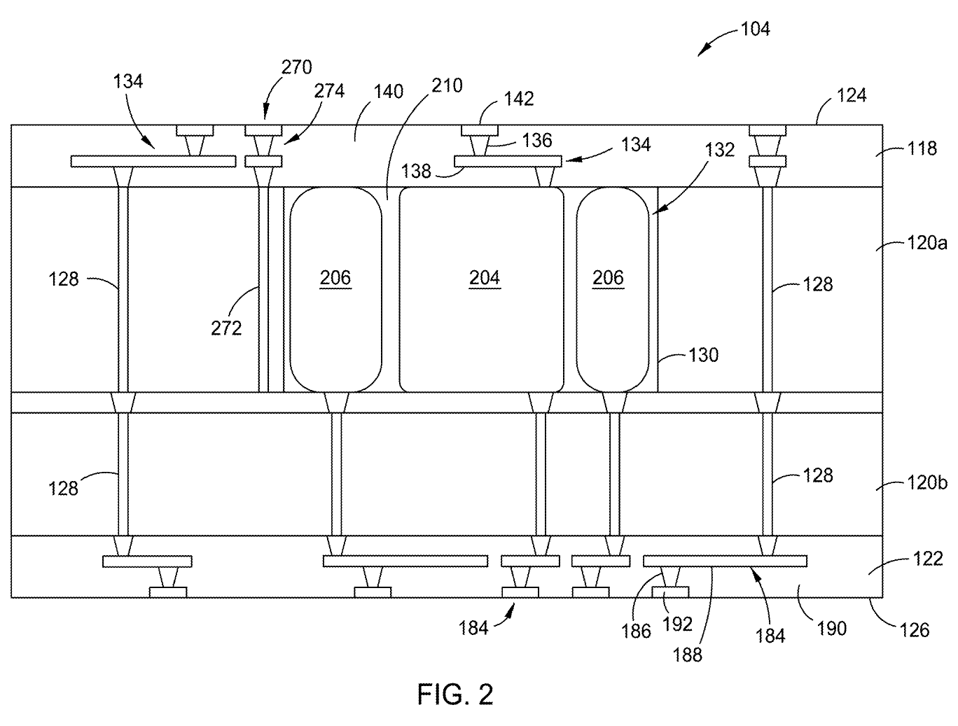

FIG. 2 is a schematic side view one example of the multi-core substrate 104 of FIG. 1. In the example depicted in FIG. 2, only one IC device 132 is illustrated embedded in the multi-core substrate 104. However, two or more IC devices 132 may be disposed in the first core 120a of the multi-core substrate 104. When multiple IC devices 132 are disposed in the first core 120a of the multi-core substrate 104, the IC devices 132 may be the same or different type of IC device 132. In one example, the IC device 132 is a pre-fabricated unitary component that is inserted into the recess 130 of the substate 104, such as in the form of a chiplet.

The IC device 132 has a first face and a second face. The first face of the IC device 132 faces the first built-up layers 118 of the multi-core substrate 104 and the IC die 102. The second face of the IC device 132 faces the second built-up layers 122 of the multi-core substrate 104. Optionally, the IC device 132 may be utilized flipped upside down. At least one of the faces of the IC device 132 includes contact pads for establishing electrical connection with the internal circuitry of the IC device 132. If communication with the internal circuitry of the IC device 132 is only desired from the side of the IC device 132 facing the first built-up layers 118, then contact pads are only needed on the first face of the IC device 132. Similarly, if communication with the internal circuitry of the IC device 132 is only desired from the side of the IC device 132 facing the second built-up layers 122, then contact pads are only needed on the second face of the IC device 132. If communication with the internal circuitry of the IC device 132 is desired from both sides of the IC device 132 that the first and second built-up layers 118, 122, then contact pads are present on both the first and second faces of the IC device 132.

The IC device 132 may be configured as either an active device 202 or a passive device 206. The active device 202 is a small, specialized, and independent integrated circuit chiplet designed to perform a specific function, such as processing, memory, or I/O. The active device 202 has circuitry configured to perform as an integrated voltage regulator (IVR), an amplifier, or logic transistors, among others. The passive device 206 has circuitry configured to perform as capacitors, inductors, resistors, and the like. The inductors may be air core inductors, magnetic core inductors, or other type of inductor.

In the example depicted in FIG. 2, the IC devices 132 embedded in the first core 120a of the multi-core substrate 104 include at least one active device 202 and at least one passive device chiplet 206. The active device 202 includes IVR circuitry. The passive devices are configured as inductors or capacitors.

The IC devices 132 are retained in the recess 130 by mold compound 210. The mold compound 210 may be an epoxy, polyurethane, silicone, or other suitable potting compound. In one example the mold compound 210 is selected to have good thermal conductivity (i.e., thermal conductivity greater than about 1.0 W/m·K) such that heat is readily passed out of the IC device 132. For example, the mold compound 210 may be a thermally conductive epoxy, thermally conductive polyurethane, or thermally conductive silicon. Thermally conductive mold compounds 210 may include aluminum oxide, boron nitride or other material that increases the thermal conductivity above the base compound.

To further enhance heat transfer away from the active device 202 and out of the first core 210a of the multi-core substrate 104, one or more thermally conductive pillars pillar 272 may be disposed through the mold compound 210. The pillar 272 may be formed from copper or other thermally conductive material, such as other metals or carbon-based materials. The pillar 272 may be part of a thermal via 270. The thermal via 270 includes a via stack 274 formed through the first module built-up layers 212. Although only one thermal via 270 is illustrated in FIG. 2, it is contemplated that the multi-core substrate 104 may include multiple thermal vias 270 to enhance heat transfer away from the active device 202, thus ensuring the performance and reliability of the active device 202.

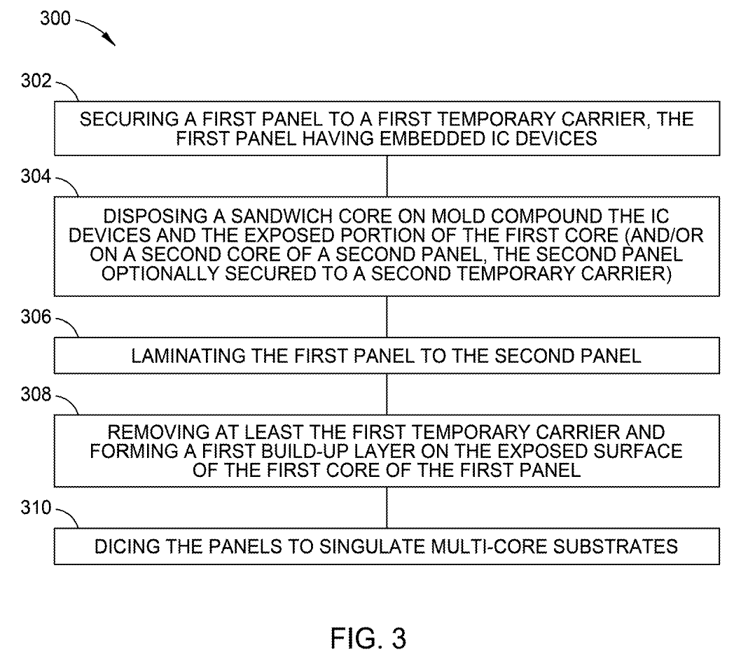

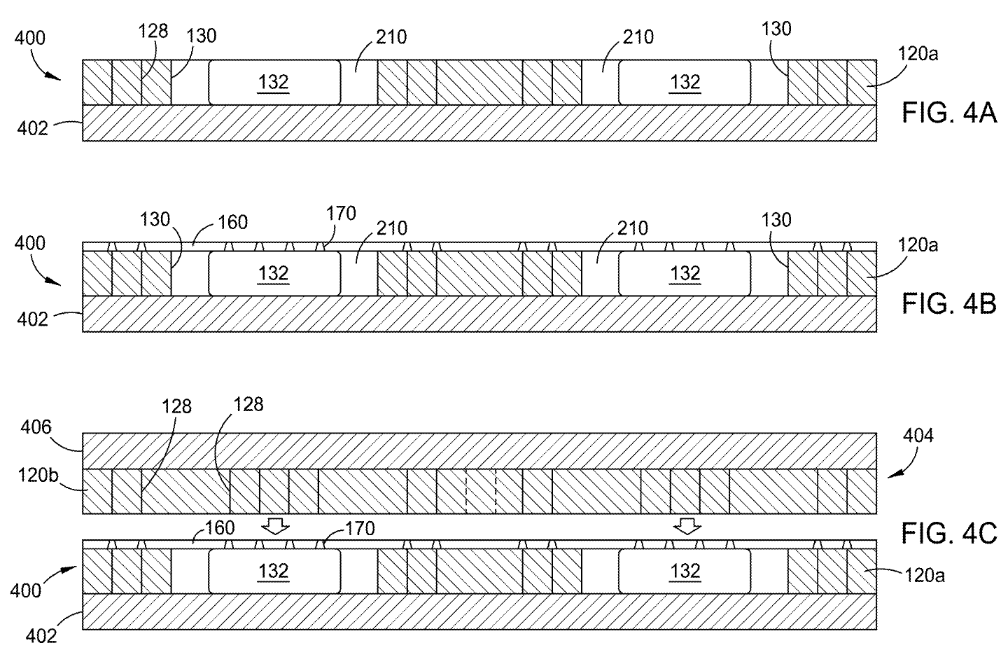

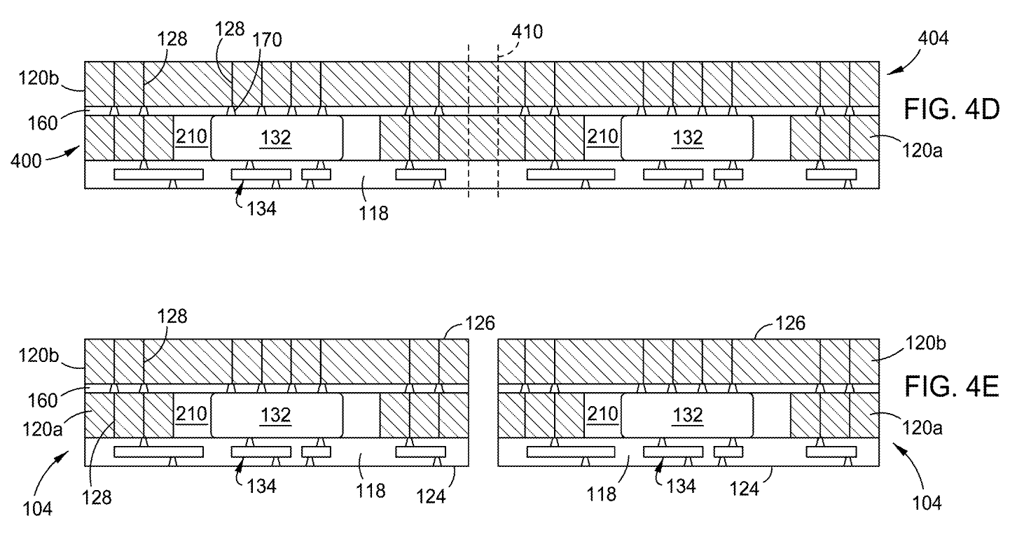

FIG. 3 is a block diagram of a method 300 for fabricating a multi-core substrate, such as but not limited to the multi-core substrate 104 depicted in FIGS. 1-2 that have one or more IC devices 132 embedded in at least one core (120a) of the multi-core substrate 104. FIGS. 4A-4E are schematic side views of the multi-core substrate 104 having an embedded IC device 132 during various stages of fabrication in accordance with the method 300.

The method 300 begins at operation 302 by securing a first panel 400 to a first temporary carrier 402, as illustrated in FIG. 4A. The first temporary carrier 402 may be an aluminum or plastic palette, or other structure having a flat surface on which the first panel 400 is secured. The first panel 400 is later diced to become the first core 120a of the multi-core substrate 104. A plurality of recesses 130 are disposed in the first core 120a. One or more IC devices 132 are disposed in each of the recesses 130. The one or more IC devices 132 may be active or passive devices (204, 206). One IC device 132 is shown in each recess 130 depicted in FIG. 4A. Mold compound 210 is disposed in the recesses to cover the IC devices 132. The electric pads of the IC devices are exposed through the mold compound 210. The first panel 400 may be secured to the first temporary carrier 402 using die attached tape or other temporary adhesive.

At operation 304, a sandwich core 160 is disposed on the mold compound 210, the IC devices 132 and the exposed portion of the first core 120a, as illustrated in FIG. 4B. The sandwich core 160 may be an adhesive layer, a propylene glycol layer, a prepreg layer, or a dielectric layer. Contacts 170 are formed through the sandwich core 160 and are electrically connected with the contact pads of the IC devices 132. Alternatively or additionally, the sandwich core 160 may be disposed the second core 120b (later shown in FIG. 4C).

At operation 306, a second panel 404 is laminated to the first panel 400 using the sandwich core 160, as illustrated in FIG. 4C. The second panel 404 maybe secured to and supported by a second temporary carrier 406, if additional rigidity is required. The second panel 404 may be laminated to the first panel 400 by heating the panels 400, 404 such that the adhesive in the sandwich core 160 cures and creates a secure bond between the panels 400, 404.

The laminated panels 400, 404 have the vias 128 of each panel 400, 404 electrically connected by the contacts 170 of the sandwich core 160. The laminated panels 400, 404 also have the contact pads of the IC device 132 electrically connected by the contacts 170 of the sandwich core 160 to the vias 128 disposed in the second core 120b.

At operation 308, at least the first temporary carrier 402 is removed and a first build-up layer 118 is formed on the exposed surface of the first core 120a of the first panel 400, as illustrated in FIG. 4D. The first build-up layer 118 includes first build-up layer circuitry 134 that is electrically coupled to the vias 132 formed in the first core 120a. The first build-up layer circuitry 134 is also electrically coupled to the IC device 132 disposed in the recess 130 of the first core 120a. Scribe lanes 410 used to singulate the panels 400, 404 are illustrated in phantom in FIG. 4D.

The first built-up layer 118 is formed by patterning metal layers disposed between dielectric layers 140. The patterned metal layers form the first built-up layer routing circuitry 134. The first built-up layer routing circuitry 134 is formed by connected lines 138 and vias 136 formed from the patterned metal layers of the first built-up layer 118.

Optionally at operation 308, the second temporary carrier 406 may also be removed. Alternatively if present, second temporary carrier 406 may be removed after the panels 400, 404 are diced to singulate the substrates 104.

Although not shown in FIG. 4D, a second build-up layer 122 may be optionally formed on the exposed surface of the second core 120b of the panel 404 at operation 308. If present as illustrated in FIG. 1, the second build-up layer 122 includes second build-up layer circuitry 184 that is electrically coupled to the vias 132 formed in the second core 120b. The second build-up layer circuitry 184 is also electrically coupled to the IC device 132 disposed in the recess 130 of the first core 120a through the contacts 170 of the sandwich core 160.

When present, the second build-up layer 122 is formed on the exposed surface of the second core 120b opposite the first built-up layer 118, as shown in FIG. 1. The second build-up layer 122 is formed by patterning metal layers disposed between dielectric layers 190. The patterned metal layers form the second build-up layer routing circuitry 184. The second build-up layer routing circuitry 184 is formed by connected lines 188 and vias 186 formed from the patterned metal layers of the second built-up layer 122. The second build-up layer routing circuitry 184 may be electrically connected to the vias 128 formed through the second core 120b. The second build-up layer routing circuitry 184 may also be electrically connected to the IC devices 128 through the vias 128 formed through the second core 120b and the contacts 170 formed through the sandwich core 160.

At operation 310, the panels 400, 404 are diced to singulate the multi-core substrates 104, as illustrated in FIG. 4E. The multi-core substrates 104 may be singulated using a wire saw or using another suitable technique. Optionally, the second temporary carrier 404 may be removed after singulation.

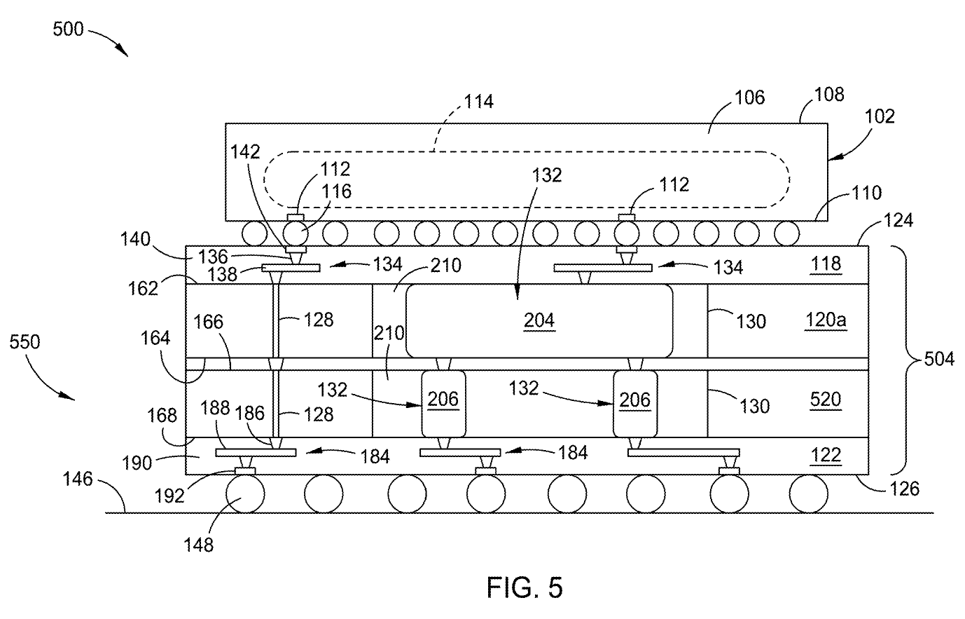

FIG. 5 is a schematic side view another example of an electronic device 550 that includes a chip package 500 having a multi-core substrate 504. The electronic device 550 and the chip package 500 of FIG. 5 are generally identical to the electronic device 150 and the chip package 100 described above with reference to FIGS. 1-4, except wherein the chip package 500 includes one or more integrated circuit (IC) devices 132 embedded in at least two cores (120a, 520) of the multi-core substrate 504. That is, instead of the second core containing no IC devices 132, the second core 520 of the multi-core substrate 504 includes one or more IC devices 132 disposed in a recess 130 formed in the second core 520. Mold compound 210 fills the recess 130 of the second core 520, substantially encapsulating one or more IC devices 132.

In the example depicted in FIG. 5, a recess 130 is formed in the second core 520. The recess 130 may be in the form of a cavity that extends from the first face 166 into the second core 520. In the example depicted in FIG. 5, the recess 130 extends from the first face 166 and exits the second face 168 of the second core 520, thus forming a passage completely through the second core 520.

One or more IC device chiplets 132 are disposed in the recess 130 of the second core 520. The IC device 132 does not extend beyond the faces 166, 168 of the second core 520. In one example, the IC device 132 is a pre-fabricated unitary component that secured in the recess 130. The one or more IC devices 132 may be active or passive devices (204, 206). Two IC devices 132 are shown in each recess 130 depicted in FIG. 5. In one example, the IC devices 132 disposed in the recesses 130 of the second core 520 are inductors or capacitors, while the IC devices 132 disposed in the recess 130 of the first core 120a are integrated voltage regulators (IVRs). The IC devices 132 disposed in the second core 520 are electrically coupled to the IC devices 132 disposed in the first core 120a by the contacts 170 formed in the sandwich core 160.

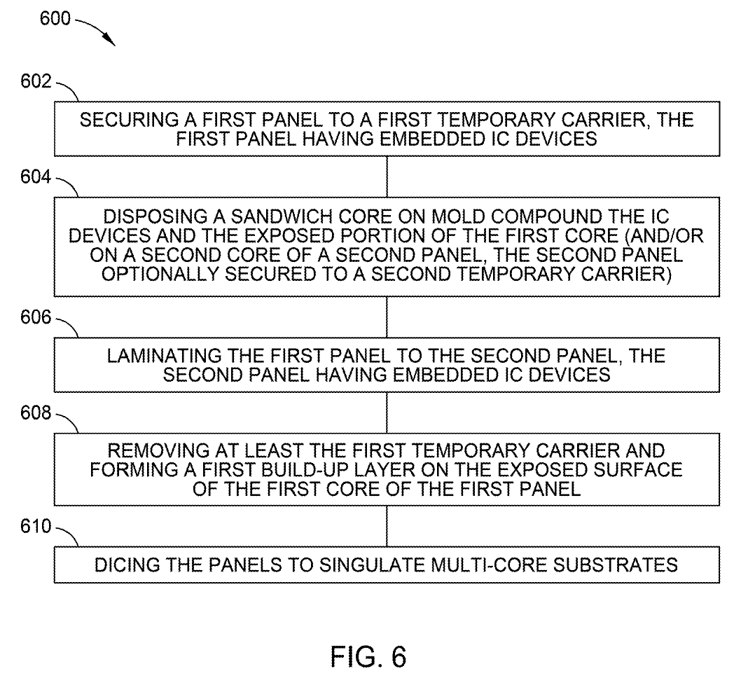

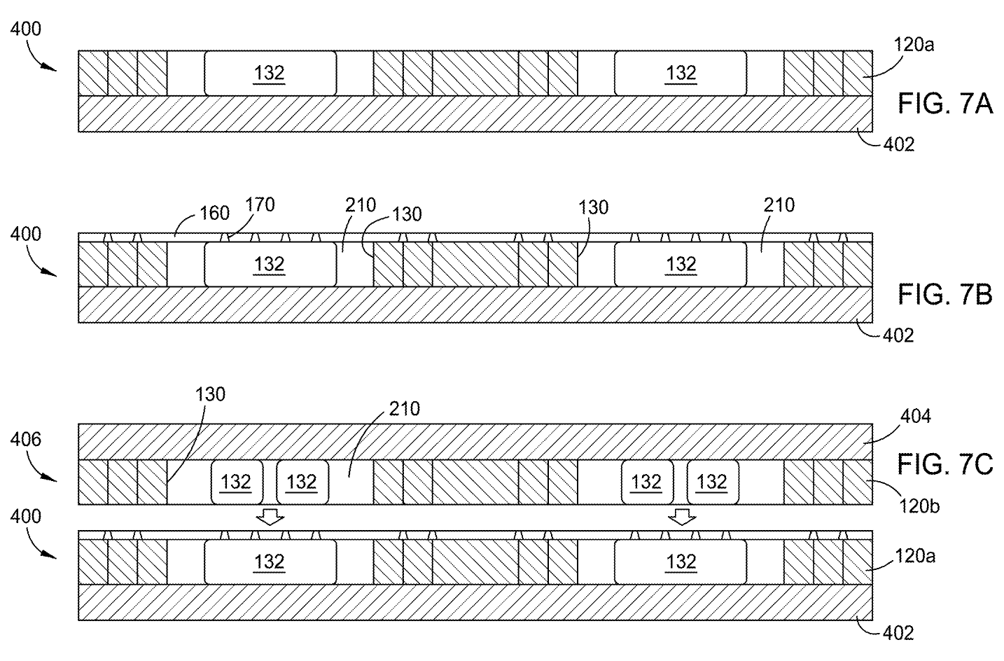

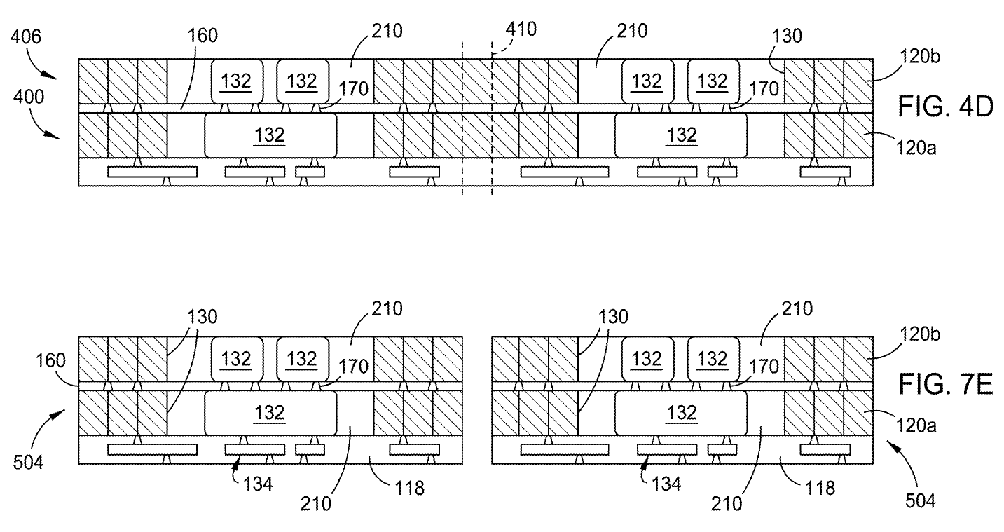

FIG. 6 is a block diagram of another method 600 for fabricating a multi-core substrate having one or more IC devices embedded in each of at least two cores of the multi-core substrate. FIGS. 7A-7E are schematic side views of another multi-core substrate having embedded IC devices during various stages of fabrication.

FIG. 6 is a block diagram of a method 600 for fabricating a multi-core substrate, such as but not limited to the multi-core substrate 504 depicted in FIG. 5 that have one or more IC devices embedded in a recess 130 of each of at least two cores (120a, 520) of the multi-core substrate 504. FIGS. 7A-7E are schematic side views of the multi-core substrate 504 having an embedded IC device 132 during various stages of fabrication in accordance with the method 600.

The method 600 begins at operation 602 by securing a first panel 700 to a first temporary carrier 702, as illustrated in FIG. 7A. The first temporary carrier 702 may be an aluminum or plastic palette, or other structure having a flat surface on which the first panel 700 is secured. The first panel 700 is later diced to become the first core 120a of the multi-core substrate 504. A plurality of recesses 130 are disposed in the first core 120a. One or more IC devices 132 are disposed in each of the recesses 130. The one or more IC devices 132 may be active or passive devices (204, 206). One IC device 132 is shown in each recess 130 depicted in FIG. 7A. Mold compound 210 is disposed in the recesses to cover the IC devices 132. The electric pads of the IC devices are exposed through the mold compound 210. The first panel 700 may be secured to the first temporary carrier 702 using die attached tape or other temporary adhesive.

At operation 604, a sandwich core 160 is disposed on the mold compound 210, the IC devices 132 and the exposed portion of the first core 120, as illustrated in FIG. 7B. The sandwich core 160 may be an adhesive layer, propylene glycol layer a prepreg layer, or a dielectric layer. Contacts 170 are formed through the sandwich core 160 and are electrically connected with the contact pads of the IC devices 132. Alternatively or additionally, the sandwich core 160 may be disposed the second core 120b (later shown in FIG. 4C).

At operation 606, a second panel 704 is laminated to the first panel 700 using the sandwich core 160, as illustrated in FIG. 7C. The second panel 704 maybe secured to and supported by a second temporary carrier 706, if additional rigidity is required. The second panel 704 may be laminated to the first panel 700 by heating the panels 700, 704 such that the adhesive in the sandwich core 160 cures and creates a secure bond between the panels 700, 704.

The second panel 704 is later diced to become the second core 504 of the multi-core substrate 504. A plurality of recesses 130 are disposed in the second core 504. One or more IC devices 132 are disposed in each of the recesses 130 of the second core 504. The one or more IC devices 132 may be active or passive devices (204, 206). Two IC devices 132 are shown in each recess 130 depicted in FIG. 7A.

The laminated panels 700, 704 have the vias 128 of each panel 700, 704 electrically connected by the contacts 170 of the sandwich core 160. The IC devices 132 disposed in each of the laminated panels 700, 704 are electrically connected by the contacts 170 of the sandwich core 160.

At operation 608, at least the first temporary carrier 702 is removed and a first build-up layer 118 is formed on the exposed surface of the first core 120a of the panel 700, as illustrated in FIG. 7D. The first build-up layer 118 includes first build-up layer circuitry 134 that is electrically coupled to the vias 132 formed in the first core 120a. The first build-up layer circuitry 134 is also electrically coupled to the IC device 132 disposed in the recess 130 of the first core 120a. Scribe lanes 710 used to singulate the panels 700, 704 are illustrated in phantom in FIG. 7D.

The first built-up layer 118 is formed by patterning metal layers disposed between dielectric layers 140. The patterned metal layers form the first built-up layer routing circuitry 134. The first built-up layer routing circuitry 134 is formed by connected lines 138 and vias 136 formed from the patterned metal layers of the first built-up layer 118.

Optionally at operation 608, the second temporary carrier 706 may also be removed. Alternatively if present, second temporary carrier 706 may be removed after the panels 700, 704 are diced to singulate the substrates 504.

Although not shown in FIG. 7D, a second build-up layer 122 may be optionally formed on the exposed surface of the second core 520 of the panel 704 at operation 608. If present as illustrated in FIG. 1, the second build-up layer 122 includes second build-up layer circuitry 184 that is electrically coupled to the vias 132 formed in the second core 520. The second build-up layer circuitry 184 is also electrically coupled to the IC device 132 disposed in the recess 130 of the second core 540.

When present, the second build-up layer 122 is formed on the exposed surface of the second core 520 opposite the first built-up layer 118, as shown in FIG. 1. The second build-up layer 122 is formed by patterning metal layers disposed between dielectric layers 190. The patterned metal layers form the second build-up layer routing circuitry 184. The second build-up layer routing circuitry 184 is formed by connected lines 188 and vias 186 formed from the patterned metal layers of the second built-up layer 122. The second build-up layer routing circuitry 184 may be electrically connected to the vias 128 formed through the second core 520. The second build-up layer routing circuitry 184 may also be electrically connected to the IC devices 128 through the vias 128 formed through the second core 520 and the contacts 170 formed through the sandwich core 160.

At operation 610, the panels 700, 704 are diced to singulate the multi-core substrates 504, as illustrated in FIG. 7E. The multi-core substrates 504 may be singulated using a wire saw or using another suitable technique. Optionally, the second temporary carrier 704 may be removed after singulation.

Thus, the multi-core substrate architecture enables high-power integrated circuit packaging by enabling precise, scalable, and economical integration of both active and passive components directly within one or more cores of the substrate. This architecture improves electrical performance and efficiency by positioning active elements closer to the die, enhances thermal management through thermally conductive materials and dedicated heat-dissipating structures, and increases manufacturing yield and reliability. Additionally, it leverages existing wafer-level processes to reduce complexity, cost, and design time, while supporting the growing demands of advanced computing systems for higher power density, improved component integration, and robust structural integrity.

The above described multi-core substrate architecture and method for fabricating the same may also be expressed in one or more of the following examples.

Example 1. An integrated circuit (IC) module including: a first core having a first face, a second face, and a cavity formed in the first core and open through the first and second faces of the first core; an IC device disposed in the cavity of the first core; and a second core having a first face laminated to the second face of the first core.

Example 2. The IC module of Example 1, further including: a sandwich core disposed between the first core the second core.

Example 3. The IC module of Example 2, wherein the sandwich core further includes: an adhesive layer, a propylene glycol layer, a prepreg layer, or a dielectric layer.

Example 4. The IC module of Example 2, wherein the sandwich core further includes: conductive vias coupling conductive vias formed in the first core with conductive vias formed in the second core.

Example 5. The IC module of Example 2, wherein the sandwich core further includes: conductive vias coupling the IC device disposed in the first core with conductive vias formed in the second core.

Example 6. The IC module of Example 2, wherein the sandwich core further includes: conductive vias coupling the IC device disposed in the first core with another IC device disposed in the second core.

Example 7. The IC module of Example 1, further including: mold compound encapsulating the IC device in the recess; and first built-up layers formed over the IC device disposed in the recess and the first face of the second core, the first built-up layers having first substrate routing circuitry coupled to circuitry of the IC device.

Example 8. The IC module of Example 1, wherein at least the IC device embedded in the first core is an integrated voltage regulator.

Example 9. The IC module of Example 8, further including: a second IC device embedded in the second core, the second IC device one of a capacitor or an inductor.

Example 10. A chip package including: a first core having a first face, a second face, and a cavity formed in the first core and open through the first and second faces of the first core; a first IC device disposed in the cavity of the first core; a second core having a first face laminated to the second face of the first core; first built-up layers formed on the first face of the first core, the first built-up layers having first substrate routing circuitry; and an integrated circuit (IC) die disposed on the first built-up layers, the IC die having functional circuitry coupled to the first IC device through the first substrate routing circuitry.

Example 11. The chip package of Example 10, wherein the first IC device has a height that is substantially the same as a thickness of the first core.

Example 12. The chip package of Example 10, wherein the first IC device embedded in the first core is an integrated voltage regulator.

Example 13. The chip package of Example 12, further including: a second IC device embedded in the first core, the second IC device one of a capacitor or an inductor.

Example 14. The chip package of Example 12, further including: a second IC device embedded in the second core, the second IC device one of a capacitor or an inductor.

Example 15. The chip package of Example 14, wherein the second IC device is embedded in a recess form in the second core, the recess formed in the second core overlapped with at least a portion of the recess formed in the first core.

Example 16. The chip package of Example 10, further including: a sandwich core disposed between the first core the second core, the sandwich core including one or more of an adhesive layer, a propylene glycol layer, a prepreg layer, or a dielectric layer.

Example 17. A chip package including: a substrate having a plurality of cores; an integrated circuit (IC) die disposed on the substrate; and a first integrated circuit (IC) device embedded in a core of the plurality of cores disposed closest to the IC die.

Example 18. The chip package of Example 17, wherein the first IC device is an integrated voltage regulator.

Example 19. The chip package of Example 18, further including: a second IC device embedded in the core disposed closest to the IC die, the second IC device one of a capacitor or an inductor.

Example 20. The chip package of Example 18, further including: a second IC device embedded in a core of the plurality of cores different than the core disposed closest to the IC die, the second IC device one of a capacitor or an inductor.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different second-case letter suffix.

While the foregoing is directed to embodiments of the present invention, other and further embodiments of the invention may be devised without departing from the basic scope thereof, and the scope thereof is determined by the claims that follow.

What is claimed is:

1. An integrated circuit (IC) module comprising:
a first core having a first face, a second face, and a cavity formed in the first core and open through the first and second faces of the first core;
an IC device disposed in the cavity of the first core; and
a second core having a first face laminated to the second face of the first core.

2. The IC module of claim 1, further comprising:
a sandwich core disposed between the first core the second core.

3. The IC module of claim 2, wherein the sandwich core further comprises:
an adhesive layer, a propylene glycol layer, a prepreg layer, or a dielectric layer.

4. The IC module of claim 2, wherein the sandwich core further comprises:
conductive vias coupling conductive vias formed in the first core with conductive vias formed in the second core.

5. The IC module of claim 2, wherein the sandwich core further comprises:
conductive vias coupling the IC device disposed in the first core with conductive vias formed in the second core.

6. The IC module of claim 2, wherein the sandwich core further comprises:
conductive vias coupling the IC device disposed in the first core with another IC device disposed in the second core.

7. The IC module of claim 1, further comprising:
mold compound encapsulating the IC device in the cavity; and
first built-up layers formed over the IC device disposed in the cavity and the first face of the second core, the first built-up layers having first substrate routing circuitry coupled to circuitry of the IC device.

8. The IC module of claim 1, wherein at least the IC device embedded in the first core is an integrated voltage regulator.

9. The IC module of claim 8, further comprising:
a second IC device embedded in the second core, the second IC device one of a capacitor or an inductor.

10. A chip package comprising:
a first core having a first face, a second face, and a cavity formed in the first core and open through the first and second faces of the first core;
a first IC device disposed in the cavity of the first core;
a second core having a first face laminated to the second face of the first core;
first built-up layers formed on the first face of the first core, the first built-up layers having first substrate routing circuitry; and
an integrated circuit (IC) die disposed on the first built-up layers, the IC die having functional circuitry coupled to the first IC device through the first substrate routing circuitry.

11. The chip package of claim 10, wherein the first IC device has a height that is substantially the same as a thickness of the first core.

12. The chip package of claim 10, wherein the first IC device embedded in the first core is an integrated voltage regulator.

13. The chip package of claim 12, further comprising:
a second IC device embedded in the first core, the second IC device one of a capacitor or an inductor.

14. The chip package of claim 12, further comprising:
a second IC device embedded in the second core, the second IC device one of a capacitor or an inductor.

15. The chip package of claim 14, wherein the second IC device is embedded in a recess form in the second core, the recess formed in the second core overlapped with at least a portion of the recess formed in the first core.

16. The chip package of claim 10, further comprising:
a sandwich core disposed between the first core the second core, the sandwich core comprising one or more of an adhesive layer, a propylene glycol layer, a prepreg layer, or a dielectric layer.

17. A chip package comprising:
a substrate having a plurality of cores;
an integrated circuit (IC) die disposed on the substrate; and
a first integrated circuit (IC) device embedded in a core of the plurality of cores disposed closest to the IC die.

18. The chip package of claim 17, wherein the first IC device is an integrated voltage regulator.

19. The chip package of claim 18, further comprising:
a second IC device embedded in the core disposed closest to the IC die, the second IC device one of a capacitor or an inductor.

20. The chip package of claim 18, further comprising:
a second IC device embedded in a core of the plurality of cores different than the core disposed closest to the IC die, the second IC device one of a capacitor or an inductor.
